(19) United States
(12) Patent Application Publication
(10) Pub. No.: US 2025/0047097 A1
(43) Pub. Date: Feb. 6, 2025

(54) ESD PROTECTION CIRCUIT AND DEVICE INCLUDING THE SAME

(71) Applicant: SAMSUNG ELECTRONICS CO., LTD., Suwon-si (KR)

(72) Inventors: Jinho Jeong, SUWON-SI (KR); Hyungeun Kim, SUWON-SI (KR)

(73) Assignee: Sogang University Research Foundation, Seoul (KR)

(21) Appl. No.: 18/788,595

(22) Filed: Jul. 30, 2024

(30) Foreign Application Priority Data
Aug. 3, 2023 (KR) 10-2023-0101794

(51) Int. Cl. H02H 9/04

(52) U.S. Cl. CPC H02H 9/046

(57) ABSTRACT

An electrostatic discharge (ESD) protection circuit includes a first pad configured to provide a first voltage, a second pad configured to provide a second voltage, an equalizing circuit including a first inductor, a second inductor, and a third inductor, an input/output pad connected to the equalizing circuit, and a diode circuit including a first diode and a second diode. An end of the first diode is connected to the first pad and another end of the first diode is connected the equalizing circuit. An end of the second diode is connected to the equalizing circuit and the first diode and another end of the second diode is connected to the second pad.

### CROSS-REFERENCE TO RELATED APPLICATION

This patent application claims priority under 35 U.S.C. § 119 to Korean Patent Application No. 10-2023-0101794, filed on Aug. 3, 2023, in the Korean Intellectual Property Office, the disclosure of which is incorporated by reference in its entirety herein.

### 1. TECHNICAL FIELD

The inventive concept relates to a semiconductor device, and more particularly, to an electrostatic discharge (ESD) protection circuit and a semiconductor device including the ESD protection circuit.

### 2. DISCUSSION OF RELATED ART

A semiconductor circuit (e.g., a chip) includes electronic components made from semiconductors, such as silicon, that control and manipulate the flow of electronic current. Semiconductor circuits may be sensitive to a high voltage or high current introduced from an externally generated electrostatic discharge or static electricity. An electrostatic discharge (ESD) phenomenon may cause a sudden and momentary flow of the high current. The high voltage or current may destroy a thin insulating film formed in the circuit or have a bad influence on a channel, thereby causing degradation of the performance of the chip. Protection circuits against ESD may be configured to protect other circuits by discharging the high voltage or the high current, which is momentarily introduced.

A semiconductor device may include an equalizing circuit to equalize received signals and equalize signals before they are transmitted. However, when the semiconductor device includes both the equalizing circuit and the protection circuit, its area, manufacturing cost, and power consumption may be excessively large.

### SUMMARY

At least one embodiment of the inventive concept provides an electrostatic discharge (ESD) protection circuit capable of performing an equalizing function and a device including the ESD protection circuit. The ESD protection circuit may have more optimal equalizing properties and reduce manufacturing costs.

According to an aspect of the inventive concept, there is provided an ESD protection circuit including a first pad, a second pad, an equalizing circuit, and a diode circuit. The first pad is configured to provide a first voltage. The second pad is configured to provide a second voltage. The equalizing circuit includes a first inductor, a second inductor, and a third inductor. The diode circuit includes a first diode and a second diode. An end of the first diode is connected to the first pad and another end of the first diode is connected the equalizing circuit. An end of the second diode is connected to the equalizing circuit and the first diode and another end of the second diode is connected to the second pad.

According to an aspect of the inventive concept, there is provided an ESD protection circuit including a first pad, a second pad, an equalizing circuit, and a diode circuit. The first pad is configured to provide a first voltage. The second pad is configured to provide a second voltage. The equalizing circuit includes a first inductor and a second inductor. The diode circuit includes a first variable resistor, a first diode, and a second diode. An end of the first diode is connected to the first pad and another end of the first diode is connected to the equalizing circuit. An end of the second diode is connected to the equalizing circuit and the first diode and another end of the second diode is connected to the second pad. The first variable resistor is connected in parallel with the first diode.

According to an aspect of the inventive concept, there is provided an ESD protection circuit including a first pad, a second pad, a third pad, a first equalizing circuit, a second equalizing circuit, a first input/output pad, a second input/output pad, and a diode circuit. The first pad is configured to provide a first voltage. The second pad is configured to provide a second voltage. The third pad is configured to provide a third voltage. The first equalizing circuit includes a first inductor, a second inductor, and a third inductor. The second equalizing circuit includes a fourth inductor, a fifth inductor, and a sixth conductor. The first input/output pad is connected to the first equalizing circuit and configured to receive a first differential signal. The second input/output pad is connected to the second equalizing circuit and configured to receive a second differential signal. The diode circuit includes a first diode, a second diode, a third diode, and a fourth diode. An end of the first diode is connected to the first pad and another end of the first diode is connected to the first equalizing circuit. An end of the second diode is connected to the first equalizing circuit and the first diode and another end of the second diode is connected to the second pad. An end of the third diode is connected to the second equalizing circuit and another end of the third diode is connected to the second pad. An end of the fourth diode is connected to the third pad, and another end of the fourth diode is connected to the second equalizing circuit and the third diode.

### BRIEF DESCRIPTION OF THE DRAWINGS

Embodiments will be more clearly understood from the following detailed description taken in conjunction with the accompanying drawings in which:

FIG. 1 illustrates a semiconductor device according to an embodiment;

FIG. 2 illustrates an electrostatic discharge (ESD) protection circuit according to an embodiment;

FIG. 3 illustrates an equalizer circuit according to an embodiment;

FIG. 4 illustrates an ESD diode circuit according to an embodiment;

FIG. 5 illustrates an ESD protection circuit according to an embodiment;

FIG. 6 illustrates an equalizer circuit of an ESD protection circuit according to an embodiment;

FIG. 7 is a graph showing characteristics according to frequency of an ESD protection circuit according to an embodiment;

FIG. 8 illustrates an ESD protection circuit according to an embodiment;

FIG. 9 illustrates an ESD protection circuit according to an embodiment implemented at a receiving terminal;

FIG. 10 illustrates an ESD protection circuit according to an embodiment implemented at a transmitting terminal;

FIG. 11 illustrates an ESD protection circuit according to an embodiment; and

FIG. 12 illustrates an ESD protection circuit according to an embodiment.

### DETAILED DESCRIPTION

Hereinafter, embodiments of the inventive concept will be described in detail with reference to the accompanying drawings.

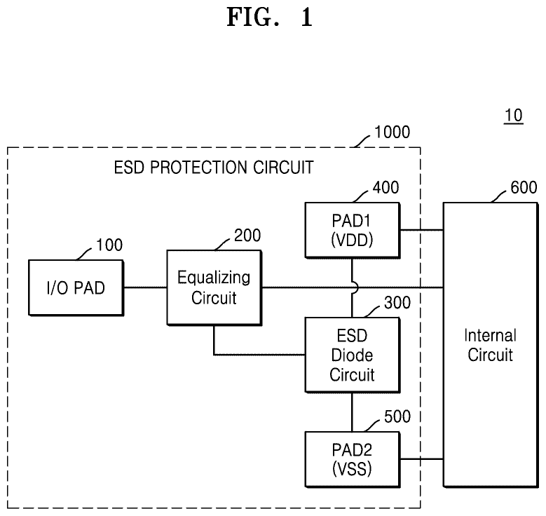

FIG. 1 is a block diagram schematically illustrating a semiconductor device 10 according to an embodiment.

Referring to FIG. 1, the semiconductor device 10 includes an electrostatic discharge (ESD) protection circuit 1000 and an internal circuit 600. The ESD protection circuit 1000 includes an input/output (I/O) pad 100, an equalizing circuit 200, an ESD diode circuit 300, a first pad 400, and a second pad 500.

When static electricity (e.g., due to ESD), is generated, the ESD protection circuit 1000 may protect the internal circuit 600 of the semiconductor device 10 based on components in the ESD protection circuit 1000. For example, when positive static electricity is applied, the positive static electricity may flow in a forward direction of at least one diode of the ESD diode circuit 300 to a terminal (e.g., the first pad 400) to which a first voltage (e.g., a power voltage VDD) is applied. In this case, at least one of other diodes of the ESD diode circuit 300 may be biased in a reverse direction, and accordingly, the positive static electricity may be prevented from flowing in the reverse direction. Alternatively, when negative static electricity is applied, the negative static electricity may flow in a forward direction of at least one diode of the ESD diode circuit 300 to a terminal (e.g., the second pad 500) to which a second voltage (e.g., a ground voltage VSS) is applied. In this case, at least one of the other diodes of the ESD diode circuit 300 may be biased in a backward direction, and accordingly, the negative static electricity may be prevented from flowing in the backward direction.

By doing so, in the ESD protection circuit 1000, a current path due to ESD may be formed between the I/O pad 100 and the first pad 400 or between the I/O pad 100 and the second pad 500. That is, the ESD protection circuit 1000 may be configured to protect the internal circuit 600 from the current due to ESD by discharging the current due to ESD through another current path.

The semiconductor device 10 may be implemented in the form of a semiconductor chip configured to input/output signals through the I/O pad 100. For example, the I/O pad 100 may be configured to receive a signal (or a signal voltage) and transmit (or apply) the signal (or the signal voltage) to the internal circuit 600.

The equalizing circuit 200 may be configured to transmit the signal, which is received through the I/O pad 100, to the internal circuit 600, based on an equalizing operation. That is, the equalizing circuit 200 may function as an equalizer. The equalizing circuit 200 may be implemented with various structures in which characteristic degradation due to parasitic capacitance and the like may be reduced. In an embodiment, the equalizing operation is performed based on the equalizing circuit 200 and/or the ESD diode circuit 300. In addition, as described above, the equalizing circuit 200 may be connected to the ESD diode circuit 300 for protection from static electricity.

The ESD diode circuit 300 may include at least two diodes. The ESD diode circuit 300 may be implemented with various structures to protect the internal circuit 600 from an ESD phenomenon. For example, the ESD diode circuit 300 may have a structure in which each of its two diodes are connected in a same direction. In an embodiment, each diode in the ESD protection circuit 300 is connected to the equalizing circuit 200, the first pad 400, or the second pad 500 and may perform an ESD protection operation.

The first pad 400 may be configured to provide the first voltage, and the second pad 500 may be configured to provide the second voltage. In an embodiment, the first voltage is the power voltage VDD, and the second voltage is the ground voltage VSS. Voltages set for the first pad 400 and the second pad 500 may be applied through conductive materials included in rails, traces, straps, wires, and the like.

The internal circuit 600 may include any type of device that needs to be protected from ESD. For example, the internal circuit 600 may include various semiconductor devices, e.g., various memory devices such as dynamic random access memory (DRAM) and flash memory, a logic device configured to construct a control circuit, and an interface device for data communication, and the like. Alternatively, the internal circuit 600 may include a circuit configured to generate data through internal calculation of the semiconductor device 10 or process data provided from outside. For example, as a data processing circuit, the internal circuit 600 may be cores of a central processing unit (CPU), a processor, and a multi-core processor, a memory, universal serial bus (USB), Peripheral Component Interconnect (PCI), a digital signal processor (DSP), a wired interface, a wireless interface, a controller, a codec, a video module (e.g., a camera interface, a Joint Photographic Experts Group) processor, a video processor, a mixer, or the like), a three-dimensional (3D) graphic core, an audio system, a driver, or the like.

The ESD protection circuit 1000 according to an embodiment is configured to simultaneously perform a ESD protection function and an equalizing function through the ESD diode circuit 300 and the equalizing circuit 200. That is, the ESD protection circuit 1000 may be configured to simultaneously function as an equalizer circuit. Since the ESD protection circuit 1000 according to an embodiment may be configured to perform an equalizing operation without additional equalizers, power consumption due to additional circuits may be reduced, and areas for the circuits may also be reduced.

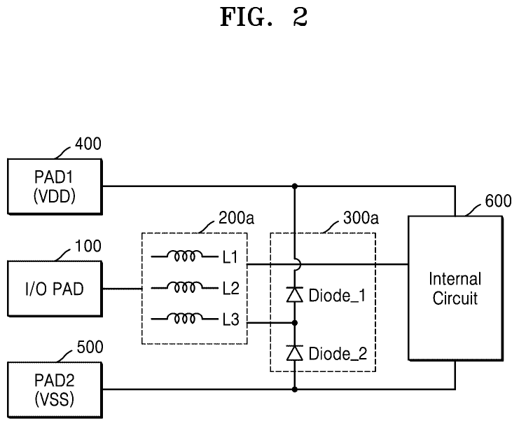

FIG. 2 is a diagram of an ESD protection circuit according to an embodiment, which may be used to implement the ESD protection circuit 1000 of FIG. 1.

Referring to FIG. 2, an equalizing circuit 200a may include a first inductor L1, a second inductor L2, and a third inductor L3, and an ESD diode circuit 300a may include a first diode Diode_1 and a second diode Diode_2. The equalizing circuit 200 of FIG. 1 may be implemented by the equalizing circuit 200a and the ESD diode circuit 300 of FIG. 1 may be implemented by the ESD diode circuit 300a.

In an embodiment, the equalizing circuit 200a includes the first inductor L1, the second inductor L2, and the third inductor L3. A structure of the equalizing circuit 200a based on the first inductor L1, the second inductor L2, and the third inductor L3 may be implemented in various forms according to the corresponding purpose. For example, the first inductor L1, the second inductor L2, and the third inductor L3 may be connected in parallel or in series. Alternatively, the structure of the equalizing circuit 200a based on the first inductor L1, the second inductor L2, and the third inductor L3 may have a structure in which serial connection and parallel connection are combined. Alternatively, for example, the first inductor L1, the second inductor L2, and the third inductor L3 may have a multi-combination inductor structure. Thus, various connection structures may be used to implement the equalizing circuit 200a and the inventive concept is not limited any particular structure.

In some embodiments, the equalizing circuit 200a may be configured to perform an equalizing operation based on the aforementioned structure. The equalizing circuit 200a may be configured to receive a signal from the I/O pad 100, perform an equalizing operation on the received signal through the first inductor L1, the second inductor L2, and the third inductor L3 to generate an equalized signal, and transmit the equalized signal to the internal circuit 600. In addition, as described above, the equalizing circuit 200a may be connected to the ESD diode circuit 300a to protect the internal circuit 600 from an ESD phenomenon.

In an embodiments, the ESD diode circuit 300a is configured to perform the ESD protection operation described with reference to FIG. 1, based on the first diode Diode_1 and the second diode Diode_2. In an embodiment, the first pad 400 is connected to an end (e.g., a cathode terminal) of the first diode Diode_1, and the equalizing circuit 200a is connected to another end (e.g., an anode terminal) of the first diode Diode_1. In an embodiment, the equalizing circuit 200a is connected to an end (e.g., a cathode terminal) of the second diode Diode_2, and the second pad 500 is connected to another end (e.g., an anode terminal) of the second diode Diode_2. That is, the ESD diode circuit 300a may be configured to protect the internal circuit 600 from a current due to ESD by discharging the current due to ESD phenomenon through another current path based on the first diode Diode_1 and the second diode Diode_2. That is, the equalizing circuit 200a may be configured to receive signals from the I/O pad 100 and transmit the signals to the internal circuit 600 through the equalizing operation, and at the same time, may be connected to the ESD diode circuit 300a and thus may protect the internal circuit 600 from the ESD phenomenon.

A configuration and/or a structure of the ESD diode circuit 300a is not limited to that illustrated in FIG. 2 and may be implemented in various forms. For example, the ESD diode circuit 300a may include additional diodes, and based thereon, may form a double-diode structure. The double-diode structure may be formed in a plurality. In addition, each of the diodes included in the ESD diode circuit 300a may have various structures, e.g., a P-type diode structure or a N-type diode structure. In addition, at least one of the diodes included in the ESD diode circuit 300a may also be implemented as a transient voltage suppressor (TVS) diode.

As a result, the ESD protection circuit according to an embodiment may be configured to perform the equalizing operation by using the equalizing circuit including a plurality of inductors and the ESD diode circuit, and at the same time, may also be configured to perform the ESD protection operation, since the equalizing circuit is connected to the ESD diode circuit.

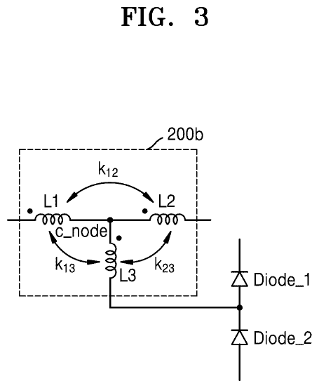

FIG. 3 illustrates an equalizing circuit 200b according to an embodiment, which may be used to implement the equalizing circuit 200a of FIG. 2.

Referring to FIG. 3, the equalizing circuit 200b may include a first inductor L1, a second inductor L2, and a third inductor L3, and may include a multi-combination inductor structure based thereon.

In an embodiment, the first inductor L1, the second inductor, and the third inductor L3 are three-terminal inductors. As shown in FIG. 3, an end of each of the first inductor L1, the second inductor L2, and the third inductor L3 are connected to a common node c_node. A coupling coefficient between the first inductor L1 and the second inductor L2 may be represented as k₁₂, a coupling coefficient between the second inductor L2 and the third inductor L3 may be represented as k₂₃, and a coupling coefficient between the first inductor L1 and the third inductor L3 may be represented as k₁₃. Polarity of a voltage of each inductor may be marked in the form of dot convention. In some embodiments, inductances of and coupling coefficients between inductors may be adjusted based on various factors, e.g., characteristics of channels configured to transmit and receive channels, characteristics of wavelength bands, and/or characteristics of circuits. For example, an inductance value may be adjusted to compensate for loss of the channels. The equalizing circuit 200b may be configured to transmit an equalized signal to the inside, based on the equalizing operation described above. In an embodiment, the second inductor L2 is connected to the internal circuit 600.

As described above with reference to FIG. 1, the equalizing circuit 200b may be connected to the ESD diode circuit 300. In an embodiment, the third inductor L3 is connected to an anode terminal of the first diode Diode_1 and a cathode terminal of the second diode Diode_2 to connect the equalizing circuit 200b to the ESD diode circuit 300.

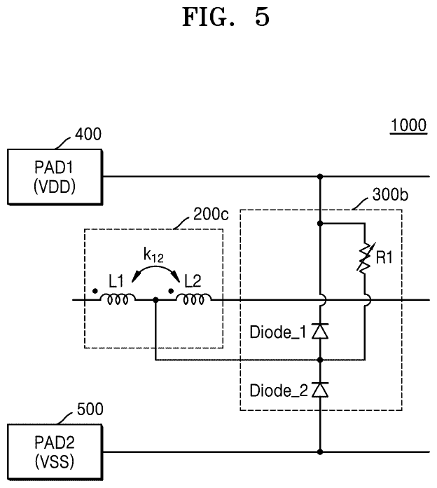

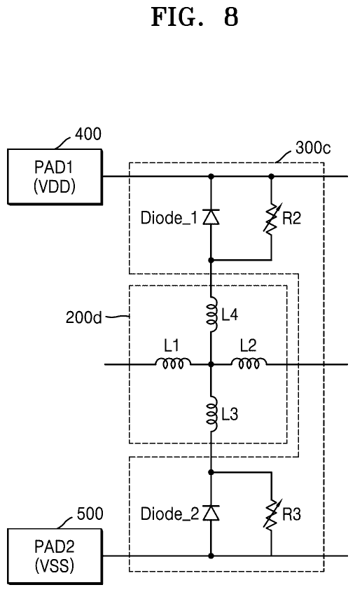

However, the structure of the equalizing circuit 200b is not limited to that illustrated in FIG. 3 and may be implemented in various forms. That is, although the equalizing circuit 200b may be implemented based on three-terminal inductors, an equalizing circuit may be implemented based on various structures (e.g., a structure suggested in FIG. 5 or FIG. 8) in which degradation of characteristics due to a parasitic capacitance of the first diode Diode_1 and the second diode Diode_2 may be reduced.

The ESD protection circuit according to an embodiment may be configured to perform the equalizing operation based on the multi-combination inductor, and at the same time, may have ESD-tolerance properties. In addition, as described above, various types of mutual inductive coupling between the inductors may be used for the ESD protection circuit according to an embodiment, and thus, the ESD protection circuit may be configured to further provide more optimal equalizing characteristics.

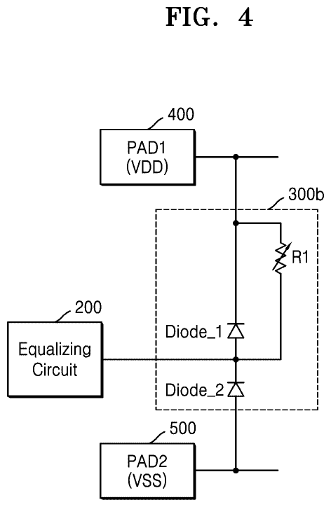

FIG. 4 illustrates an ESD diode circuit 300b according to an embodiment, which may be used to implement the ESD diode circuit 300a of FIG. 2.

Referring to FIG. 4, the ESD diode circuit 300b may include the first diode Diode_1, the second diode Diode_2, and a first variable resistor R1, and may be connected to the first pad 400 and the second pad 500 to perform ESD protection operation.

The equalizing circuit 200 may be connected to the ESD diode circuit 300b, and a current due to ESD may be discharged through a current path based on the first pad 400, the second pad 500, and the ESD diode circuit 300b.

In an embodiment, equalizing properties of the equalizing circuit 200 may be further optimized through the first variable resistor R1 of the ESD diode circuit 300b. That is, the equalizing circuit 200 and the ESD diode circuit 300b may be configured to perform both of the equalizing operation and the ESD protection operation through interaction. In an embodiment, the first variable resistor R1 is connected to the first diode Diode_1 in parallel. By adjusting a resistance value of the first variable resistor R1, the equalizing properties may be properly adjusted. For example, an additional circuit may be present for automatically adjusting the resistance value or the resistance value may be manually adjusted as needed. More particularly, for example, by adjusting the resistance value of the first variable resistor R1, an equalizing circuit configured to compensate for loss (e.g., attenuation property) of a high-frequency band by adjusting a low-frequency band may be implemented.

That is, in the ESD protection circuit according to an embodiment, when the diodes used for ESD protection and at least one variable resistor is connected in parallel, equalizing properties may be further optimized based on the parasitic capacitances of the diodes and resistance values of the variable resistors, and equalizing may be adjusted as needed. Accordingly, in the ESD protection circuit according to an embodiment, power consumption and circuit areas may be significantly reduced by combining ESD protection and a more optimized equalizing operation in a single circuit.

FIG. 5 illustrates the ESD protection circuit 1000 according to an embodiment.

Referring to FIG. 5, the equalizing circuit 200c may include the first inductor L1 and the second inductor L2, and the ESD diode circuit 300b connected to the first pad 400 and the second pad 500 may include the first diode Diode_1, the second diode Diode_2, and the first variable resistor R1. The equalizing circuit 200c may be used to implement the equalizing 200a of FIG. 2 and the ESD diode circuit 300b may be used to implement the ESD diode circuit 300a of FIG. 2.

As described above with reference to FIG. 4, the equalizing circuit 200c may be implemented as various structures, and in some embodiments, the equalizing circuit 200 may be implemented in a structure where the first inductor L1 and the second inductor L2 are combined with each other. The ESD protection circuit 1000 may be configured to perform an equalizing operation based on the first inductor L1 and the second inductor L2 of the equalizing circuit 200c (e.g., based on inductances of the first inductor L1 and the second inductor L2 and the coupling coefficient k₁₂ between each other). In addition, the ESD protection circuit 1000 may be configured to further optimize equalizing properties by adjusting the resistance value of the first variable resistor R1 of the ESD protection circuit 300b. Signals received through the equalizing circuit 200c may flow through a current path based on the ESD diode circuit 300b, and accordingly, the ESD protection circuit 1000 may also have ESD robustness. The second inductor L2 may be connected to the internal circuit 600.

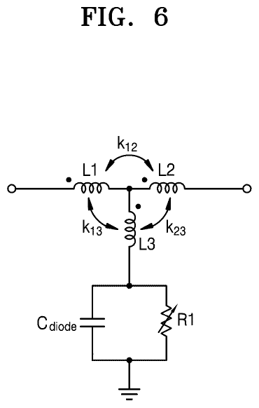

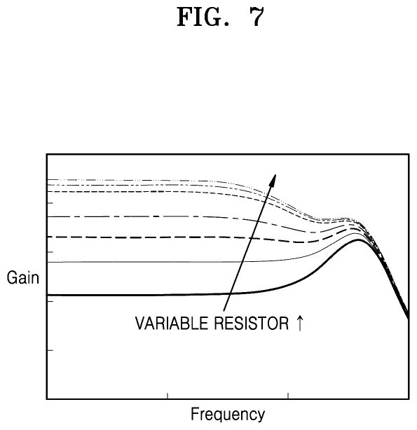

FIG. 6 is a circuit diagram of an equivalent circuit of an ESD protection circuit according to an embodiment. FIG. 7 is a graph showing characteristics according to frequency of an ESD protection circuit according to an embodiment.

Referring to FIGS. 3 and 4, the ESD protection circuit according to an embodiment may be configured to perform an equalizing operation, based on a three-terminal inductor including the first inductor L1, the second inductor L2, and the third inductor L3 and the first variable resistor R1, and may also be configured to perform an ESD protection operation based on the diodes (i.e., the first diode Diode_1 and the second diode Diode_2).

Referring to FIG. 6, a parasitic capacitance generated by the diodes included in the ESD diode circuit may represented by C_{diode}, and the equivalent circuit of the ESD protection circuit may be configured based thereon. In a low-frequency band, inductors have low impedances, and therefore, the impedances of the first inductor L1, the second inductor L2, and the third inductor L3 may have relatively lower values. On the contrary, capacitors have high impedances, and thus, the resistance value of the first variable resistor R1 connected thereto in parallel may dominantly work. Accordingly, loss of the low-frequency band may be adjusted according to the resistance value of the first variable resistor R1.

Referring to FIG. 7, change in the loss in the low-frequency wave band may be represented by the resistance value of the first variable resistor R1. As shown in FIG. 7, according to an increase in the resistance value of the first variable resistor R1, the loss in the low-frequency band may be reduced. In addition, peaking in the high-wave frequency band may be used according to the resistance value of the first variable resistor R1, and by doing so, loss due to channel characteristics and the like may be compensated. In this way, by adjusting the value of the variable resistor, operations of the circuit may be more efficiently adjusted according to various characteristics.

FIG. 8 is a circuit diagram of an example of an ESD protection circuit according to an embodiment.

Referring to FIG. 8, an equalizing circuit 200d may include the first inductor L1, the second inductor L2, the third inductor L3, and a fourth inductor L4, and an ESD diode circuit 300c may include the first diode Diode_1, the second diode Diode_2, a second variable resistor R2, and a third variable resistor R3.

In an embodiments, the equalizing circuit 200d includes a four-terminal inductor structure. In an embodiment, the first inductor L1, the second inductor L2, the third inductor L3, and the fourth inductor L4 share a same node and are connected to one another. The equalizing circuit 200d may be configured to perform an equalizing operation based on an inductance of each of the first inductor L1, the second inductor L2, the third inductor L3, and the fourth inductor LA, and/or coupling coefficients among the inductors.

The fourth inductor L4 may be connected to an anode terminal of the first diode Diode_1, the third inductor L3 may be connected to a cathode of the second diode Diode_2. Thus, the equalizing circuit 200d may be connected to the ESD diode circuit 300c. Since a cathode of the first diode Diode_1 is connected to the first pad 400 and an anode of the second diode Diode_2 is connected to the second pad 500, the ESD diode circuit 300c may be configured to perform the ESD protection operation.

In some embodiments, as described with reference to FIG. 4, the second variable resistor R2 may be connected to the first diode Diode_1 in parallel, and the third variable resistor R3 may be connected to the second diode Diode_2 in parallel. By adjusting a resistance value of the second variable resistor R2 and/or a resistance value of the third variable resistor R3, equalizing properties may be further improved optimized. For example, loss due to the channels may be compensated based on the resistance values. The second inductor L2 may be connected to the internal circuit 600. The fourth inductor L4 may be connected in series with the third inductor L3, and the first inductor L1 may be connected in series with the second inductor L2.

That is, by using the ESD protection circuit according to an embodiment, more optimized equalizing properties may be obtained based on various types of mutual inductance combination among the inductors, and furthermore, the equalizing properties may be variously adjusted and optimized by connecting the variable resistors and the diodes in parallel. In addition, in the ESD protection circuit according to an embodiment, discharge paths may be separated from one another through the four-terminal inductor, and by doing so, the robustness may be further increased.

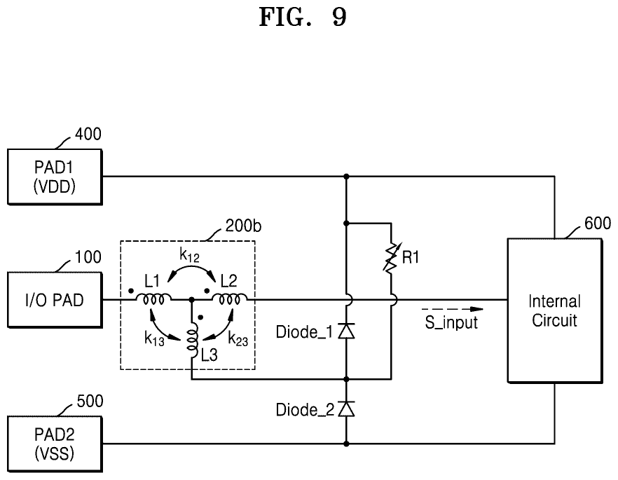

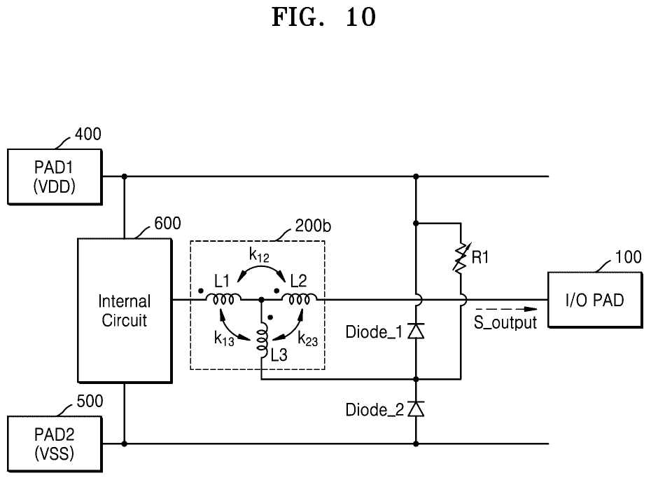

FIG. 9 illustrates an ESD protection circuit according to an embodiment implemented at a receiving terminal. FIG. 10 illustrates an ESD protection circuit according to an embodiment implemented at a transmitting terminal.

Referring to FIGS. 9 and 10, the ESD protection circuit according to an embodiment may be applied to a transmitting terminal and a receiving terminal of the semiconductor device. In some embodiments, the equalizing circuit 200b may be implemented in various structures to perform the equalizing operation, e.g., the three-terminal inductor structure as described above with reference to FIG. 3. In addition, as described above with reference to FIG. 4, the first resistance R1 may be connected in parallel with the first diode Diode_1 configured to perform the ESD protection operation and may optimize the equalizing properties.

In some embodiments, referring to FIG. 9, the I/O pad 100 may be configured to receive a signal (or a signal voltage) from outside and transmit the signal to the equalizing circuit 200b. The equalizing circuit 200b may be configured to receive the signal from the I/O pad 100 and perform an equalizing operation on the received signal to generate an equalized signal S_input. The equalizing circuit 200b may be configured to output the equalized signal S_input to the internal circuit 600. That is, the ESD protection circuit according to an embodiment may be located at the receiving terminal of the semiconductor device and equalize a signal to transmit to the internal circuit of the semiconductor device, and at the same time, may be configured to protect the internal circuit 600 based on the first diode Diode_1 and the second diode Diode_2 when a current is generated due to ESD. In an embodiment, the input/output pad 100 is connected in series with the first inductor L1.

In some embodiments, referring to FIG. 10, the equalizing circuit 200b may be configured to receive, from the internal circuit 600, a signal (or a signal voltage) to output to the outside. In this case, the equalizing circuit 200b may be used to reduce a limitation in a bandwidth due to the parasitic capacitances of the first diode Diode_1 and the second diode Diode_2. The equalizing circuit 200b may be configured to transmit a signal to output S_output to the I/O pad 100. That is, the ESD protection circuit according to an embodiment may be located at the transmitting terminal of the semiconductor device and provide more optimal bandwidth properties, and at the same time, may be configured to protect the internal circuit 600 based on the first diode Diode_1 and the second diode Diode_2 when the current is generated due to ESD. In an embodiment, the I/O pad 100 is connected in series with the second inductor L2.

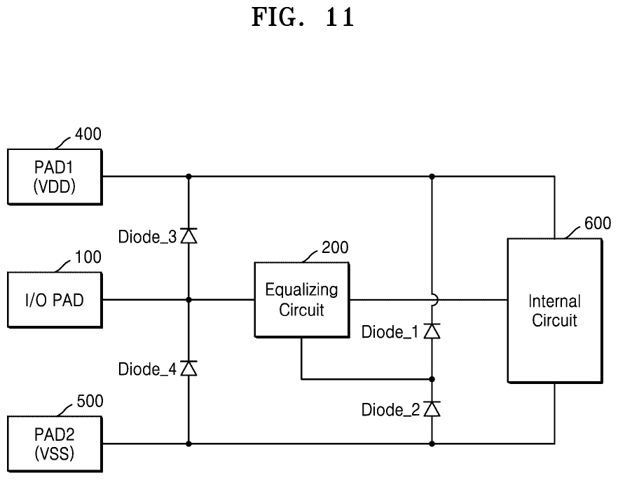

FIG. 11 illustrates an ESD protection circuit according to an embodiment.

Referring to FIG. 11, the ESD protection circuit may be configured to perform ESD protection functions based on the first diode Diode_1, the second diode Diode_2, the third diode Diode_3, and the fourth diode Diode_4. As described above with reference to FIG. 2, the first diode Diode_1 and the second diode Diode_2 may form a current path by being respectively connected to the first pad 400 and the second pad 500, and by doing so, may protect the internal circuit 600 from the current due to ESD.

In some embodiments, the ESD protection circuit may further include the third diode Diode_3 and the fourth diode Diode_4 to increase ESD protection. More particularly, ESD protection devices, i.e., the third diode Diode_3 and the fourth diode Diode_4 may be separated from the equalizing circuit 200. For example, the first pad 400 may be connected to a terminal (e.g., a cathode) of the third diode Diode_3, and an end (e.g. a cathode terminal) of the fourth diode Diode_4 may be connected to another end (e.g., an anode terminal) of the third diode Diode_3. The second pad 500 may be connected to another end (e.g., an anode terminal) of the fourth diode Diode_4. That is, in the ESD protection circuit according to an embodiment, in connection to the first pad 400 and the second pad 500, additional ESD protection devices may be arranged closer to the first pad 400 and the second pad 500 than the diodes (i.e., the first diode Diode_1 and the second diode Diode_2) connected to the equalizing circuit 200 and thus may be separated from the diodes connected to the equalizing circuit 200, and by doing so, ESD tolerance properties, as well as reflective loss, may be increased. In an embodiment, a distance between the third diode Diode_3 and the first pad 400 is less than a distance between the first diode Diode_1 and the first pad 400; and a distance between the fourth diode Diode_4 and the second pad 500 is less than a distance between the second diode Diode_2 and the second pad 400. In an embodiment, distances between the third and fourth diodes Diode_3 and Diode_4 and the first and second pads 400 and 500, are less than distances between the first and second diode Diode_1 and Diode_2 and the first and second pads 400 and 500.

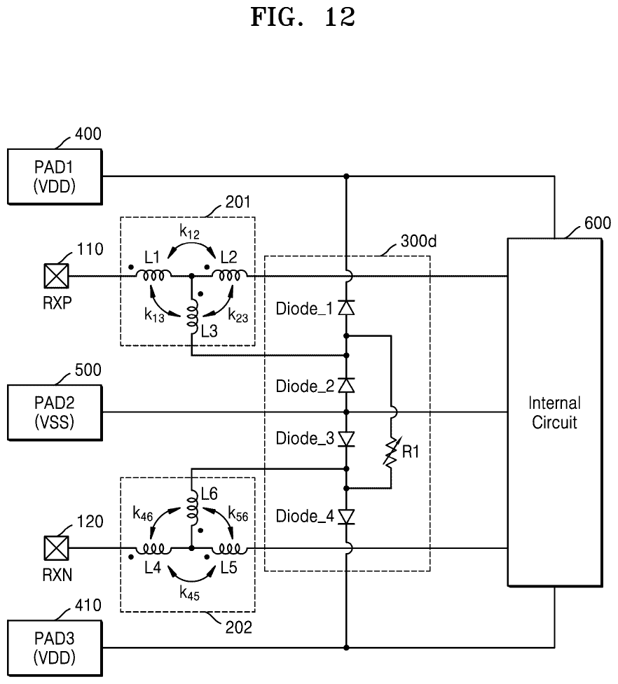

FIG. 12 illustrates an ESD protection circuit according to an embodiment.

Referring to FIG. 12, the ESD protection circuit may be configured to receive and process a differential signal. The ESD protection circuit may include an equalizing circuit including a first differential equalizing circuit 201 and a second differential equalizing circuit 202, an ESD diode circuit 300d, the first pad 400, the second pad 500, and a third pad 410, and may be configured to protect the internal circuit 600 from the ESD phenomenon.

In some embodiments, the first differential equalizing circuit 201 may include the first inductor L1, the second inductor L2, and the third inductor L3. The first inductor L1, the second inductor L2, and the third inductor L3 may be used to construct an equalizing circuit through various combination structures. For example, the first inductor L1, the second inductor L2, and the third inductor L3 may be connected to a same node to construct a three-terminal inductor. In this case, coupling coefficients between each two of the first inductor L1, the second inductor L2, and the third inductor L3 may be marked as k₁₂, k₂₃, and k₁₃. The equalizing properties may be controlled by adjusting an inductance of each inductor and/or a coupling coefficients between each two of the inductors. The first differential equalizing circuit 201 may be configured to receive a first differential signal RXP from a first receiving terminal 110 (e.g., the I/O pad), perform the equalizing operation as described above on the first differential signal RXP to generate an equalized signal, and transmit the equalized signal to the internal circuit 600. The first differential equalizing circuit 201 may be connected to the ESD diode circuit 300d to protect the internal circuit 600 from the ESD phenomenon occurring at the first receiving terminal 110 and the like.

The second differential equalizing circuit 202 may include the fourth inductor L4, the fifth inductor L5, and the sixth inductor L6. The fourth inductor L4, the fifth inductor L5, and the sixth inductor L6 may be used to construct an equalizing circuit through various combination structures. For example, the fourth inductor L4, the fifth inductor L5, and the sixth inductor L6 may be connected to a same node to construct a three-terminal inductor. In this case, the coupling coefficients between two of the fourth inductor LA, the fifth inductor L5, and the sixth inductor L6 may be marked as k₄₆, k₅₆, and k₄₅. The equalizing properties may be adjusted by adjusting an inductance of each inductor and/or a coupling coefficient between each two of the inductors. The second differential equalizing circuit 202 may be configured to receive a second differential signal RXN from a second receiving terminal 120 (e.g., the I/O pad), perform the equalization operation on the second differential signal RXN as described above to generate an equalized signal, and transmit the equalized signal to the internal circuit 600. The second differential equalizing circuit 202 may be connected to the ESD diode circuit 300d to protect the internal circuit 600 from the ESD phenomenon occurring at the second receiving terminal 120 and the like.

In some embodiments, the ESD diode circuit 300d may include the first diode Diode_1, the second diode Diode_2, the third diode Diode_3, and the fourth diode Diode_4, and may provide the aforementioned ESD protection operation based thereon. For example, the first pad 400 may be connected to an end (e.g., a cathode terminal) of the first diode Diode_1, and the first differential equalizing circuit 201 may be connected to another end (e.g., an anode terminal) of the first diode Diode_1. The first differential equalizing circuit 201 may be connected to an end (e.g., a cathode terminal) of the second diode Diode_2, and the second pad 500 may be connected to another end (e.g., an anode terminal) of the second diode Diode_2. The second differential equalizing circuit 202 may be connected to an end (e.g., a cathode terminal) of the third diode Diode_3, and the second pad 500 may be connected to another end (e.g., an anode terminal) of the third diode Diode_3. The third pad 410 may be connected to an end (e.g., a cathode terminal) of the fourth diode Diode_4, and the second differential equalizing circuit 202 may be connected another end (e.g., an anode terminal) of the fourth diode Diode_4.

In this way, the ESD diode circuit 300d may protect the internal circuit 600 by forming another current path based on the first diode Diode_1, the second diode Diode_2, the third diode Diode_3, and the fourth diode Diode_4 and discharging the current generated due to the ESD phenomenon. That is, the ESD protection circuit may be configured to perform the equalizing operation such that the first differential signal RXP and the second differential signal RXN respectively received through the first receiving terminal 110 and the second receiving terminal 120 may be transmitted to the internal circuit 600 and protect the internal circuit 600 from the ESD phenomenon.

In some embodiments, as described above with reference to FIG. 4, the ESD diode circuit 300d may further include the first variable resistor R1, and the equalizing properties may be further optimized through the first variable resistor R1. For example, an end of the first variable resistor R1 may be connected to an anode terminal of the first diode Diode_1, and another end of the first variable resistor R1 may be connected to an anode terminal of the fourth diode Diode_4. In this case, since the first variable resistor R1 is not directly connected to the second pad 500 (e.g., a ground voltage VSS), impacts due to the variable resistor may be reduced. In addition, by setting the first variable resistor R1 to have a great resistance value, a leakage current flowing to the variable resistor may also be reduced.

That is, the ESD protection circuit according to an embodiment may also be used to process data transmitted based on differential signals, and since the equalizing circuits and the ESD diode circuit are properly set and constructed, the performance in a differential method as well as equalizing properties and ESD tolerance properties may be enhanced, and the leakage current may also be reduced.

While the inventive concept has been particularly shown and described with reference to embodiments thereof, it will be understood that various changes in form and details may be made therein without departing from the spirit and scope of the following claims.

What is claimed is:

1. An electrostatic discharge (ESD) protection circuit comprising:
a first pad configured to provide a first voltage;
a second pad configured to provide a second voltage;
an equalizing circuit comprising a first inductor, a second inductor, and a third inductor; and
a diode circuit comprising a first diode and a second diode,
wherein an end of the first diode is connected to the first pad and another end of the first diode is connected to the equalizing circuit, and
an end of the second diode is connected to the equalizing circuit and the first diode, and another end of the second diode is connected to the second pad.

2. The ESD protection circuit of claim 1,
wherein the first inductor, the second inductor, and the third inductor construct a three-terminal inductor having a common node, and
the third inductor is connected to the first diode and the second diode.

3. The ESD protection circuit of claim 1,
wherein the diode circuit further comprises a first variable resistor, and
the first variable resistor is connected in parallel with the first diode.

4. The ESD protection circuit of claim 1,
wherein the equalizing circuit further comprises a fourth inductor having a common node with the first inductor, the second inductor, and the third inductor,
the fourth inductor is connected in series with the first diode, and
the third inductor is connected in series with the second diode.

5. The ESD protection circuit of claim 4,
wherein the diode circuit further comprises a second variable resistor and a third variable resistor,
the second variable resistor is connected in parallel with the first diode, and
the third variable resistor is connected in parallel with the second diode.

6. The ESD protection circuit of claim 2,
further comprising an input/output pad configured to receive a signal and transmit the signal to the equalizing circuit,
wherein the input/output pad is connected in series with the first inductor.

7. The ESD protection circuit of claim 2,
further comprising an input/output pad configured to receive, from the equalizing circuit, a signal, which is to be output,
wherein the input/output pad is connected in series with the second inductor.

8. The ESD protection circuit of claim 1,
wherein the diode circuit further comprises a third diode and a fourth diode connected in series with each other,
the third diode is connected to the first pad,
the fourth diode is connected to the second pad,
the third diode and the fourth diode are connected in parallel with the first diode and the second diode, and are connected to the first pad and the second pad closer than the first diode and the second diode are connected.

9. The ESD protection circuit of claim 1, wherein at least one of the first diode and the second diode comprises a transient voltage suppressor (TVS) diode.

10. The ESD protection circuit of claim 1,
wherein at least one of inductances of the first inductor, the second inductor, and the third inductor and coupling coefficients between two of the first inductor, the second inductor, and the third inductors is adjustable.

11. An electrostatic discharge (ESD) protection circuit comprising:
a first pad configured to provide a first voltage;
a second pad configured to provide a second voltage;
an equalizing circuit comprising a first inductor and a second inductor; and
a diode circuit comprising a first diode, a second diode, and a variable resistor,
wherein an end of the first diode is connected to the first pad and another end of the first diode is connected to the equalizing circuit,
an end of the second diode is connected to the equalizing circuit and the first diode, and another end of the second diode is connected to the second pad, and
the variable resistor is connected in parallel with the first diode.

12. The ESD protection circuit of claim 11,
wherein the first inductor and the second inductor are connected in series with each other through a common node, and
the equalizing circuit is connected to the first diode and the second diode through the common node.

13. The ESD protection circuit of claim 11,
wherein the equalizing circuit further comprises a third inductor having a common node with the first inductor and the second inductor, and
the third inductor is connected to the first diode and the second diode.

14. The ESD protection circuit of claim 12,
further comprising an input/output pad configured to receive a signal and transmit the signal to the equalizing circuit,
wherein the input/output pad is connected in series with the first inductor.

15. The ESD protection circuit of claim 12,
further comprising an input/output pad configured to receive, from the equalizing circuit, a signal, which is to be output,
wherein the input/output pad is connected in series with the second inductor.

16. The ESD protection circuit of claim 14,
wherein the diode circuit further comprises a third diode and a fourth diode connected in series with each other,
the third diode is connected to the first pad,
the fourth diode is connected to the second pad,
the third diode and the fourth diode are connected in parallel with the first diode and the second diode, and are connected to the first pad and the second pad closer than the first diode and the second diode.

17. The ESD protection circuit of claim 11, wherein at least one of inductances of the first inductor and the second inductor and a coupling coefficient between the first inductor and the second inductor is adjustable.

18. An electrostatic discharge (ESD) protection circuit comprising:
a first pad configured to provide a first voltage;
a second pad configured to provide a second voltage;
a third pad configured to provide a third voltage;
a first equalizing circuit comprising a first inductor, a second inductor, and a third inductor;
a second equalizing circuit comprising a fourth inductor, a fifth inductor, and a sixth inductor;
a first input/output pad connected to the first equalizing circuit to receive a first differential signal;
a second input/output pad connected to the second equalizing circuit to receive a second differential signal; and
a diode circuit comprising a first diode, a second diode, a third diode, and a fourth diode,
wherein an end of the first diode is connected to the first pad and another end of the first diode is connected to the first equalizing circuit,
an end of the second diode is connected to the first equalizing circuit and the first diode, and another end of the second diode is connected to the second pad,
an end of the third diode is connected to the second equalizing circuit, and another end of the third diode is connected to the second pad, and
an end of the fourth diode is connected to the third pad, and another end of the fourth diode is connected to the second equalizing circuit and the third diode.

19. The ESD protection circuit of claim 18,
wherein the diode circuit further comprises a variable resistor,
an end of the variable resistor is connected to a common node of the first diode and the second diode, and
another end of the variable resistor is connected to a common node of the third diode and the fourth diode.

20. The ESD protection circuit of claim 18,
wherein the first inductor, the second inductor, and the third inductor construct a three-terminal inductor having a common node, and
the fourth inductor, the fifth inductor, and the sixth inductor construct a three-terminal inductor having a common node,
the third inductor is connected to the first diode and the second diode, and
the sixth inductor is connected to the third diode and the fourth diode.
